(19) United States
(12) Patent Application Publication
(10) Pub. No.: US 2017/0229668 A1
(43) Pub. Date: Aug. 10, 2017

(54) TRANSPARENT ELECTRODE MATERIALS AND METHODS FOR FORMING SAME

(71) Applicant: Flinders Partners Pty Ltd, South Australia (AU)

(72) Inventors: Andrew John Stapleton, Wayville (AU); David Andrew Lewis, Marion (AU); Joseph George Shapter, Happy Valley (AU); Gunther Gerolf Andersson, Mount Barker (AU); Jamie Scott Quinton, Christies Beach (AU); Amanda Ellis, Coromandel Valley (AU)

(21) Appl. No.: 15/501,994

(22) PCT Filed: Aug. 7, 2015
(86) PCT No.: PCT/AU2015/000473

§ 371 Date: Feb. 6, 2017

(30) Foreign Application Priority Data
Aug. 7, 2014 (AU) 2014903060

(51) Int. Cl. H01L 51/44; H01B 5/14; H01B 1/04; H01B 1/12; H01L 51/00; H01B 1/02

(52) U.S. Cl. CPC H01L 51/444; H01L 51/0021; H01B 1/02; H01B 1/04; H01B 1/124; H01B 5/14

(57) ABSTRACT

A transparent electrode material including a conductive layer having an active surface and a second surface, and an adjacent base layer, wherein: ∘ the conductive layer includes a conductive network formed by metallic nanowires and carbon nanotubes encapsulated in a conductive material; ∘ the second surface of the conductive layer has encapsulated nanowires and/or nanotubes projecting therefrom; and ∘ the encapsulated nanowires and/or nanotubes projecting from the second surface of the conductive layer are embedded in the adjacent base layer; whereby the active surface of the conductive layer is smooth and electrically active, and the transparent electrode material has a sheet resistance less than 50 Ω/sq and a transparency greater than 70%.

### TECHNICAL FIELD

The present invention relates to transparent electrode materials, and methods for forming those materials, the materials being suitable for use in the fabrication of optoelectronic devices (ideally flexible optoelectronic devices), and being a nanocomposite of metallic nanowires and carbon nanotubes.

### BACKGROUND OF INVENTION

Optoelectronic devices such as flat panel displays, solar cells and light emitting diodes, and the more recently emerging technologies of organic photovoltaic devices, organic light emitting diodes, and touch screens, rely on transparent electrodes for optical transparency and conductivity. Indium tin oxide (ITO) has become the most utilized material for transparent electrodes due to its desirably low sheet resistance (15 to 60 Ω/sq) and desirably high optical transparency (>90%).

In recent years, there has been increasing interest in the production of flexible electronics. Flexibility enables thin film electronics to be manufactured via scalable roll-to-roll (R2R) techniques, greatly reducing the expense and energy required to manufacture electronic devices. ITO deposited onto flexible polyethylene terephthalate (PET) substrates is commercially available for such uses. However, studies have shown that the resistivity of ITO thin film increases significantly upon bending. The increase in resistivity has been attributed to the formation of cracks throughout the thin ITO film.

Also, ITO tends to be the most expensive component of most current optoelectronic technologies. For example, life-time-cost-analysis of conventional organic photovoltaic (OPV) devices shows that up to 87% of the total lifetime energy cost is attributable to the ITO. Thus, the potential energy savings by removing ITO from OPV devices has accelerated research into alternative transparent electrode materials and composites, combined with the drive to fabricate flexible transparent electrodes. However, the flexibility must not come at a cost to other advantageous properties such as optical transparency and appropriately aligned work functions, thus ensuring subsequent optoelectronic devices are as efficient as conventionally fabricated thin film devices on ITO electrodes

Nanometric materials have been gaining momentum as an alternative transparent electrode material due to their ease of manufacture, high conductivity and mechanical ductility (and hence their usability for flexible electrodes). However, a drawback to using nanometric materials as an ITO replacement is that the nanometric materials formed typically have a high surface topography. The peak-to-trough height can be in the micrometre regime, over which thin films of organic materials are unable to conform, particularly where efficient optoelectronic devices tend to require active layers to have a thickness in the order of 200 nm. Indeed, rough surfaces such as these can introduce shorting pathways in an optoelectronic device, shorting pathways being a contributing factor to the reduction of device efficiency, again fuelling the research drive to the development of nanometric materials that permit easy fabrication of smooth active surfaces

For example, reference is made to U.S. Pat. No. 8,198,796B2 to Hiroshi Takada (“the Takada document”) where this problem is described with reference to two prior art documents (that the Takada document describes as “Patent Documents 3 and 4”) that suggest the use of nanometric materials such as metallic nanowires. The Takada document identifies as a problem the suggestions in these two prior art documents to form a transparent electrode material with metallic nanowires protruding from a transparent resin film, the problem being the use of such a material when surface smoothness of an electrode is required.

In contrast, the Takada document then goes on to exemplify the formation of a three dimensional conductive network of metallic nanowires fully embedded in a conductive material (its TC-10 to TC-14 in Example 1), providing comparative examples (TC-17 and TC-19) of the suggestions from Patent Documents 3 and 4 to only partially embed metallic nanowires in a UV hardenable resin and then overcoat the UV hardenable resin with a conductive material, leaving metallic nanowires protruding from the surface. In this respect, the Takada document again highlights the failure of the comparative examples TC-17 and TC-19, and thus recommends against the adoption of these forms.

The alternative exemplified by the Takada document, namely the formation of a conductive network of metallic nanowires (or, in its Example 3, of carbon nanotubes) fully embedded in a conductive material is said to avoid these problems and permit the formation of desirably smooth electrode surfaces, albeit with the necessary use of a separate (and additional) binder material between the conductive material and the base material.

However, despite the quantity of research into the use of nanometric materials for transparent electrodes, difficulties remain in the production of nanometric transparent electrode materials with a surface roughness comparable to ITO, and which also permit acceptable electrical performance.

Transparent electrodes fabricated to date from metallic nanowires such as silver nanowires (AgNW) typically have a surface roughness incompatible with the production of efficient devices. In this respect, AgNW has been embedded into a poly(3,4-ethylenedioxythiophene):poly(styrenesulfonate) (PEDOT:PSS) layer via a stamping technique to achieve smooth transparent electrodes and has produced organic solar cells with comparable efficiency to devices fabricated on ITO. Also, AgNW/polyacrylate electrodes have been produced with a surface roughness of less than 5 nm via a lift-off procedure from a glass substrate, with the sheet resistance reported to be 30 Ω/sq. Furthermore, a lift-off technique has been suggested to create stretchable transparent electrodes of AgNW and polydimethylsiloxane (PDMS) with >80% transmittance with an average sheet resistance of >35 Ω/sq.

These AgNW transparent electrode materials all have acceptably high optical transmission as they consist of a sparse nanowire network embedded into a polymer matrix with spaces of up to 1 μm within the AgNW network. However, these spaces have been found to effect the diffusion of free carriers in optoelectronic devices, which rely on a continuous conduction pathway to ensure efficient extraction of free charges generated within an active layer.

Therefore, a second interpenetrating conducting material in the form of carbon nanotubes, such as single wall carbon nanotubes (SWCNT), has been suggested to bridge the AgNW network and to act as an additional charge collection network to collect charges from the active layer.

However, despite the encouraging properties of transparent electrode materials formed from such AgNW/SWCNT composites, further work has been required to permit the use of such materials in the fabrication of optoelectronic devices as electrically efficient as traditional ITO-based optoelectronic devices. The present invention thus aims to provide a transparent electrode material suitable for use in the fabrication of optoelectronic devices, including flexible devices, ideally being a material that does not require the adoption of post-production planarising techniques in order to form smooth active surfaces.

### SUMMARY OF INVENTION

The present invention provides a transparent electrode material including a conductive layer having an active surface and a second surface, and an adjacent base layer, wherein:
the conductive layer includes a conductive network formed by metallic nanowires and carbon nanotubes encapsulated in a conductive material;
the second surface of the conductive layer has encapsulated nanowires and/or nanotubes projecting therefrom; and
the encapsulated nanowires and/or nanotubes projecting from the second surface of the conductive layer are embedded in the adjacent base layer;
   whereby the active surface of the conductive layer is smooth and electrically active, and the transparent electrode material has a sheet resistance less than 50 Ω/sq and a transparency greater than 70%.

The physical arrangement of the conductive layer and the base layer of the electrode material of the present invention thus sees the second surface of the conductive layer being immediately adjacent to a first surface of the base layer (there being no intervening resin layer), with what could be described as the “top” surface of the electrode material being the active surface of the conductive layer and what could be described as the “bottom” surface of the electrode material being, in at least one form of the present invention, a rear surface of the base layer. However, it is to be appreciated that the use of these terms is not to imply a particular in-use orientation for the electrode material of the present invention, nor is it to restrict the configuration generally described. Also, the use of these terms does not imply that other functional layers may not be added to either or both sides of the electrode material. Indeed, as will be described below, other functional layers, on either or both sides, will often be utilised in various in-use scenarios.

The metallic nanowires and carbon nanotubes of the conductive layer are preferably silver nanowires and single-walled carbon nanotubes, such that the conductive layer of the electrode material preferably has a conductive network in the form of silver nanowires and single-walled carbon nanotubes encapsulated in a conductive material. However, it will be appreciated that other metallic nanowires may be utilised, such as gold or platinum nanowires, and other carbon nanotubes may be utilised, such as double-wall or multi-wall carbon nanotubes.

In a preferred form, the conductive layer will have a thickness of between about 5 nm and 300 nm, noting that this thickness is the distance between the active surface and the second surface.

The conductive network is preferably provided by intimate contact between nanowires and nanotubes, and also between nanowires, nanotubes and the conductive material of the conductive layer. Ideally, the intimate contact between nanowires and nanotubes is due to the nanowires and nanotubes being interwoven, such as in a randomly distributed network of nanowires and nanotubes, providing multiple pathways for charges to be transported and a large number of contact points, and thus efficient transport channels of charge carriers to provide high electrical conductivity to the conductive layer. Additionally, the intimate contact and interweaving of the nanowires and nanotubes facilitates the formation of an electrode through a continuous process by providing a mechanical stability to the conductive elements.

The conductive material that encapsulates the nanowires and nanotubes, forming a matrix about the nanowires and nanotubes, is able to provide several functions. The conductive material of such a nanocomposite should ideally be such as to allow transport of electrons to the nanowires and nanotubes, albeit typically only over small distances of the type that would be regarded as “gaps” between a randomly distributed interwoven network of nanowires and nanotubes. With this in mind, it will be appreciated that the conductive material will have filled these gaps, including gaps that might have otherwise been at the active surface and that might have rendered the active surface undesirably discontinuous. In this respect, the filling of the gaps by the conductive material assists in ensuring that the material of the base layer does not, during formation of the electrode material, seep through the network of nanowires and nanotubes, disrupting the conductive network and reaching the active surface.

The conductive material thus should also be such as to provide secondary transport channels of charge carriers through the active surface of the conductive layer, to enable carrier transport from an OPV (or whatever is electrically adjacent to the active surface) via the nanowires and nanotubes, which are the primary transport channels of charge carriers and which are in intimate contact with conductive material. At least some of the nanowires and nanotubes remain electrically exposed at the active surface, rendering the active surface both smooth and electrically active.

With regard to the use of the word “smooth” to characterise the active surface, it is recognised that this is a relative term, particularly given the nanoscale application of the present invention. In this respect, a skilled addressee will appreciate that the requirement for a smooth surface finish for the active surface of the transparent electrode material depends on the desired application for that electrode material, and such a skilled addressee will be able to determine if an active surface is suitably smooth.

By way of example, for an OPV in which the thickness of adjacent layers such as the bulk hetero-junction is of the order of 80 nm, the root mean square (rms) surface roughness of the electrode surface will ideally be less than about 10 nm, and preferably below about 5 nm, as measured over a region of up to about 10 micrometres. It will also be appreciated that a peak-to-trough range of up to about 50 nm in such a device would be acceptable, provided the variation is over a sufficiently large distance on the surface to avoid short circuits by the peaks penetrating thorough the adjacent layers and contacting subsequent layers. A skilled addressee will understand that both of these parameters are being used in this example to represent an active surface that is suitably smooth in terms of the present invention.

Given the abovementioned likely variation (due to the many possible applications for the electrode materials of the present invention) in what might be regarded as suitably smooth, and thus not wishing to be limited to particular height profiles for the surface topography of an ideal active surface (in terms of smoothness), in one form of the present invention it can be said that the active surface ideally has a surface topography with a height profile having a peak-to-trough height of less than 50 nm.

The conductive material should also be of a type that permits the electrode material of the present invention to be flexible and transparent, and that ideally also provides acceptable adhesion to, and encapsulation of, the nanowires and nanotubes, together with acceptable adhesion for the conductive layer to the base layer.

In terms of the functionality of electrode materials in accordance with the present invention, and of products or devices formed from these electrode materials, it is preferable for the electrodes to be flexible enough such that they can survive a bend radius of 5 mm without a change in conductivity. Having said that, in many uses for the electrode material of the present invention, electrodes will be acceptably flexible if they are able to be subjected to a bend radius of 100 mm using roll-to-roll processes, again without a change in conductivity

The conductive material will also preferably be substantially transparent in the wavelength range of interest to the application of an electrode formed from the electrode material. This can be achieved by the conductive material being thin enough to be provide transparency and/or the absorption being in a different region of the spectrum than that required by the device incorporating an electrode formed from the electrode material.

The conductive material is ideally selected from a group of materials comprising semi-conducting polymers, metal oxides, and ultrathin metal films. In this respect, it should be noted that a reference in this specification to a material that is a “conductive” material includes a material that might be regarded by a skilled addressee as being “partially” conductive. It will be appreciated that such a material is of course still conductive.

More specifically, suitable semi-conducting polymers include poly(3,4-ethylenedioxythiophene):polystyrene sulfonate (PEDOT:PSS), poly(3-hexylthiophene-2,5-diyl) (P3HT), poly[(9,9-di-n-octylfluorenyl-2,7-diyl)-alt-(benzo[2,1,3]thiadiazol-4,8-diyl)] (F8BT), poly(9,9′-dioctyluorene-co-bis-N,N′-(4-butylphenyl)-bis-N, N′-phenyl-1,4-phenylenediamine) (PFB), and poly(9,9′-dioctyluorene-co-bis-N,N′-(4-butylphenyl)-bis-N,N′-phenyl-1,4-phenylenediamine) (PCDTBT). Suitable metal oxides include ZnO and MoO, including doped versions of these such as AZO (aluminium doped ZnO) and Ni doped MoO, and these metal oxide materials could be deposited as contiguous films (by physical deposition), nanoparticles, or from precursor solutions which often form nanoparticulate surfaces. Ultrathin metal films include Au, Ag, Al and the like.

In this respect, careful selection of the conductive material can provide additional attributes and benefits that are important to electrodes, such as controlling the work function of the active layer (its operation as either an anode or a cathode), adhesion, wetting of subsequent layers, and the like.

The conductive layer has an active surface and a second surface, with the active surface being smooth and electrically active and, importantly, with nanowires and/or nanotubes projecting from and beyond the second surface, which is in surprising contrast to the suggestions in the prior art.

In terms of the conductive material “encapsulating” the nanowires and nanotubes, it must be appreciated that this term encompasses some portion of some nanowires and nanotubes being electrically exposed at the active surface to provide that work function for that surface, and also encompasses the nanowires and/or nanotubes that project beyond the second surface being coated (either completely or substantially) by the conductive material. These coated projecting nanowires and nanotubes, before the incorporation of the base layer, would thus have recognisable nanowire and nanotube shapes that project beyond a reasonably flat major surface that forms the so-called “second surface” of the conductive layer.

In this respect, the projecting nanowires and nanotubes are intended to be completely encapsulated, but it will be appreciated by a skilled addressee that this is unlikely to be technically achievable when fabricating the electrode material, primarily due to the nanoscale of the nanowires and nanotubes, their random arrangement, and the techniques used to introduce the conductive material when forming the conductive layer. A skilled addressee is thus to understand the use of the term “encapsulated” in this context when considering the extent of the coating of the nanowires and nanotubes that project beyond the second surface, that coating ideally being complete encapsulation, but likely being merely substantially complete encapsulation.

The base layer that is located immediately adjacent to the conductive layer, such that the base layer is upon (and intimately contacts and bonds to) the second surface of the conductive layer, to embed the encapsulated and projecting nanowires and nanotubes and to thereby form (with the conductive layer) the electrode material of the present invention, may additionally provide a function such as adhesion to a substrate, such as glass, polyethylene terephthalate (PET), polyethylene naphthalate (PEN), or a polyimide film such as poly (4,4′-oxydiphenylene-pyromellitimide) (known as Kapton K or Kapton HN). Alternatively, the base layer may itself function as a standalone substrate.

The base layer additionally provides structural and mechanical support for the electrode material, albeit ideally still permitting the electrode material to be flexible, and is able to function as a transfer layer in manufacturing techniques, as will be described below. In a preferred form, the base layer will have a thickness of between about 1 micron and 1000 microns.

Ideally the base layer should be transparent in the spectral range of interest, and should be ductile to enable the electrode to be bent and flexed without substantial cracking. With this in mind, the material of the base layer is ideally selected from a group of materials comprising thermosetting materials, such as epoxy resins, polyurethanes, and the like, and thermoplastic materials, such as ethylene vinyl acetate (EVA) and the like.

The desired morphology of the metallic nanowires and carbon nanotubes for use in the conducting network of the electrode material of the present invention will now be described. In a preferred form, suitable metallic nanowires (such as silver nanowires) will ideally be in the range of 1 to 50 μm long, with a diameter of approximately 15 to 300 nm. Suitable carbon nanotubes (such as single-walled carbon nanotubes) will ideally have a bundle diameter in the range of 5 to 150 nm, with individual nanotubes being in the range of 1 to 60 nm diameter.

In terms of the amount and proportion of nanowires and nanotubes in the conducting network, this specification will define these preferred parameters by reference to an area loading concentration (mg/m²) of nanowires in the conductive layer, and by reference to a fraction (wt %) of nanotube weight with reference to the combined nanotube and nanowire weight in the conducting network.

In this respect, it has been found that for a given nanowire area loading, as the nanotube weight fraction increases, the specular transparency (a measure of transmission) decreases. Noting the aim to maintain transmission at a level above 70%, the nanotube weight fraction will preferably be maintained in the conductive network at a level between 1 and 80 wt %, or more preferably at a level between 5 and 50% and most preferably between 15 and 30 wt %. In this respect, it has also been found that as the nanotube weight fraction increases, the sheet resistance decreases to a minimum at about 20 wt %, presumably due to the presence of enough bridging nanotubes between adjacent nanowires, which then act as a conductive interconnecting material.

Additionally, it has been found that there is a precipitous decrease in sheet resistance above a certain area loading of nanowires. As the size of the nanowires changes (with reference to both length and width), and as the method of deposition of the nanowires is altered, the preferred minimum area loading has been found to change. Similarly, as with the density of the nanowires, preferred area loadings also change. With this in mind, and in very general terms, it has been found that an optimum area loading of nanowires is just above the precipitous decrease in sheet resistance, as it has been found that this also typically corresponds to the highest transmission for a given conductive network.

With reference to preferred area loading concentrations (mg/m²) of nanowires, it is preferred that the conductive network is such that between 10 and 250 mg/m² of nanowires are loaded at the active surface. In further preferred forms, this range is between 50 and 200 mg/m², or between 70 and 150 mg/m², or between 80 and 130 mg/m².

In another form of the present invention, the electrode material may include the same configuration and composition of the conductive layer/base layer combination described above, but the base layer may additionally be located adjacent to a second conductive layer, such that the electrode material includes a single base layer located between two similar conductive layers, there thus being two active surfaces, both being smooth.

In this alternative form, the second conductive layer will also include its own conductive network formed by metallic nanowires and carbon nanotubes encapsulated in a conductive material, and having a smooth active surface and a second surface, the second surface of the second conductive layer also having encapsulated nanowires and/or nanotubes projecting therefrom, with these projecting nanowires and/or nanotubes also being embedded in the base layer, albeit in the side of the base layer opposite the first conductive layer.

Therefore, in another form of the present invention there is provided a transparent electrode material including a first conductive layer having an active surface and a second surface, a second conductive layer having an active surface and a second surface, and a base layer between the first and second conductive layers, wherein:
the active surface of the first conductive layer and the active surface of the second conductive layer are smooth;
the first and second conductive layers each include a conductive network formed by metallic nanowires and carbon nanotubes encapsulated in a conductive material such that the active surfaces are electrically active;
the second surface of the first conductive layer and the second surface of the second conductive layer both have encapsulated nanowires and/or nanotubes projecting therefrom; and
the encapsulated nanowires and/or nanotubes projecting from the second surface of the first conductive layer and the second surface of the second conductive layer are embedded in the base layer;
   whereby the transparent electrode material has a sheet resistance less than 50 Ω/sq and a transparency greater than 70%.

In this second form of the invention, it is envisaged that aspects of the two conductive layers of the transparent electrode material will be the same as those aspects described above with regard to the transparent electrode material that has only a single conductive layer, such as the nature of the conducting network (including morphology and composition of the nanowires and nanotubes), the conductive layer thickness, the active surface smoothness, and the nanowire and nanotube encapsulation.

The conducting material can either be the same for both conductive layers or it can be different, for example providing an electrode with either different or the same work functions at the active surface. If the conductive material was different on each conductive layer, it would allow the work functions to be tuned for specific functions, such as providing a structure with one active surface acting as an anode and the other active surface acting as a cathode.

Similarly, in this second form of the invention, it is envisaged that all aspects of the base layer of the transparent electrode material will be the same as those aspects described above with regard to the transparent electrode material that has only a single conductive layer, such as the selection of material for the base layer, and of base layer function and thickness. In this respect, the base layer can act as either a “spacer” layer preventing electrical interconnectivity and effectively isolating the conductive layers from each other by being insulating and/or sufficiently thick, or it can enable electrical interconnection between the conductive layers by allowing the projected nanowires and nanotubes from each conductive layer to contact each other, or conductivity between the conductive layers to be facilitated by the base layer being conductive itself.

It is envisaged that this second form of the invention will find particular use in situations where a double-sided electrode is required, such as for tandem solar cells where electrodes of different work functions are required, or in batteries. The double sided electrodes have comparable resistivity (12Ω) as single sided electrodes as measured by two point contact at a distance of 2 cm on the electrode surface.

Having described features of the transparent electrode material itself, it should be appreciated that the present invention is also embodied in a method of forming a transparent electrode material of the above general type, aspects of which will now be described.

The present invention thus also provides a method of forming a transparent electrode material the method including:
forming a network of metallic nanowires and carbon nanotubes;
encapsulating the nanowire and nanotube network in a conductive material to form a conductive network in a conductive layer such that the conductive layer has a smooth active surface that is electrically active and a second surface, and such that the second surface has encapsulated nanowires and/or nanotubes projecting therefrom;
forming a base layer upon the second surface of the conductive layer to embed the projecting nanowires and nanotubes in the base layer;
   whereby the transparent electrode material has a sheet resistance less than 50 Ω/sq and a transparency greater than 70%.

Ideally, the nanotubes will be pre-treated prior to their combining with the nanowires in the conductive network, in order to enhance the dispersability of the nanotubes, reducing their bundle size and therefore increasing the number of possible connections with the nanowires and reducing the negative impact on the transmission. Suitable methods to minimise bundling of nanotubes, and thus enhance dispersion, include exposure of the nanotubes to an acid reflux, such as with nitric acid solutions (or a combination of sulphuric and nitric acids) to cut and clean the nanotubes.

Improved sheet resistance and transmission, for the same nanotube weight fraction, have been found to occur after acid refluxing, permitting higher nanotube weight fractions to be adopted (above 20 wt % but below 50 wt %) if desired, while still maintaining acceptably low sheet resistance and acceptable high transmission. For example, at 50 wt % without an acid reflux, a sheet resistance of about 24 Ω/sq and a transmission of about 60% were obtainable, whereas those figures improved to a sheet resistance of about 11 Ω/sq and a transmission of about 76% after acid reflux of the nanotubes.

In this respect, as commercially sourced nanotubes may have variable amounts of carbonaceous and other materials included, it will be appreciated that specific treatment conditions may need to be varied in order to achieve the final combination of desired transparency and conductivity.

Further, the close interaction of the nanowires and nanotubes in the conductive network assists with the preferred adoption of a stamp transfer step for the formation of the nanowire/nanotube network. In a preferred form, to be suitable for a subsequent roll-to-roll electrode formation process, nanotubes are preferably co-deposited with nanowires to increase the efficacy of transfer to a planar template substrate during electrode fabrication. Without the presence of the nanotubes, the nanowires form a dense network after transfer from a cellulose ester membrane, with a somewhat higher sheet resistance suggesting that the network is not as well interconnected.

However, by co-depositing nanowires with, for example, about 20 wt % nanotubes, significantly lower sheet resistivities have been found to be achievable (such as in the range of 11 to 18Ω/□). Additionally, by utilising a stamp transfer process, the sheet resistance has been lower still and has also given rise to a lower standard deviation in sheet resistance readings, relecting better reproducibility with this preferred form of the process.

Finally, and in relation to the embodiment where the electrode material includes the same configuration and composition of the conductive layer/base layer combination described above, but the base layer is additionally located adjacent to a second conductive layer, such that the electrode material includes a single base layer located between two similar conductive layers, the present invention further provides a method of forming a transparent electrode material the method including:
forming a first network of metallic nanowires and carbon nanotubes;
encapsulating the first nanowire and nanotube network in a conductive material to form a first conductive network in a first conductive layer such that the first conductive layer has a smooth active surface that is electrically active and a second surface, and such that the second surface has encapsulated nanowires and/or nanotubes projecting therefrom;
forming a base layer upon the second surface of the first conductive layer such that the nanowires and nanotubes projecting from the second surface of the first conductive layer are embedded in the base layer;
forming a second network of metallic nanowires and carbon nanotubes;
encapsulating the second nanowire and nanotube network in a conductive material to form a second conductive network in a second conductive layer upon the base layer such that the second conductive layer has a smooth active surface that is electrically active and a second surface, and such that encapsulated nanowires and/or nanotubes project from the second surface of the second conductive layer to be embedded in the base layer;
   whereby the transparent electrode material has a sheet resistance less than 50 Ω/sq and a transparency greater than 70%.

The present invention will now be further described by the following non-limiting examples. It is to be understood that the following description is for the purpose of describing particular embodiments only and is not intended to be limiting with respect to the above description.

### BRIEF DESCRIPTION OF DRAWINGS

In the accompanying drawings:

FIG. 1 is a schematic representation of an embodiment of a transparent electrode material in accordance with the present invention.

FIG. 2 is a schematic representation of the instrumental set-up used for the purposes of the experimental work conducted to provide the following examples.

FIG. 3 is a schematic representation of a preferred laminator stamp and epoxy transfer method used for the fabrication of exemplary planar AgNW/SWCNT electrodes on a substrate.

FIG. 4 is a graphical representation of the impact of area loading variations in AgNWs showing the percolation threshold and variations in sheet resistance and specular transparency.

FIG. 5 is a graphical representation of comparative transmission (% T) and the reflectivity (% R) results for a prior art ITO electrode and an exemplary planar AgNW/SWCNT 80/20 w/w % electrode, with the substrate contribution removed. The sheet resistance, shown on the right, are an average of 15 measurements on 3 separate 25 mm² samples.

FIGS. 6(a) and 6(d) are tilted scanning electron microscopy images (SEMs) of (a) non-planarised AgNW and SWCNTs on a glass substrate and (d) AgNWs/SWCNT electrode after the planarisation process embedded into PEDOT:PSS and epoxy. Scale bars are 2 μm.

FIGS. 6(b) and 6(e) are topographical atomic force microscopy measurements (AFMs) of (b) non-planarised AgNW and SWCNTs on glass and (e) AgNWs and SWCNTs after the planarisation process embedded into PEDOT:PSS and epoxy. Scale bars are 2 μm.

FIGS. 6(c) and 6(f) are the height profiles along the dotted lines in FIGS. 5(b) and 5(e) respectively.

FIGS. 7(a) and 7(b) are (a) height and (b) peak force current maps of an exemplary planarised AgNW/SWCNT electrode surface with a bias voltage of 2 V.

FIG. 8 is a graphical representation of the JV characteristics of OPV devices on exemplary planarised AgNW/SWCNT electrodes with P3HT:PCBM and PCDTBT:PC70BM active layers.

### DETAILED DESCRIPTION OF PREFERRED EMBODIMENTS

The following description outlines experimental work for the preparation of exemplary transparent electrode materials in accordance with the present invention. Specifically, exemplary transparent electrode materials of these embodiments are as illustrated in FIG. 1 and include a single conductive layer 10 and a base layer 12 that is non-conductive. The conductive layer 10 is a conductive network formed by metallic nanowires 14 and carbon nanotubes 16, which in these embodiments are the preferred silver nanowires (AgNW) and single-walled carbon nanotubes (SWCNT) encapsulated in a preferred conductive material 18.

The conductive layer has a smooth active surface 20 and a second surface 22, noting that the second surface 22 of the conductive layer 10 has encapsulated nanowires 24 and/or nanotubes 26 projecting therefrom. In this respect, the projecting nanowires and/or nanotubes are embedded in the base layer 12, and are shown to be almost completely encapsulated by the conductive material, with the exception of some breaks 28 in the encapsulation coating.

In particular, the following paragraphs report on the production of a conductive network of AgNW/SWCNT encapsulated in a PEDOT:PSS conductive material, with an epoxy base layer. The following paragraphs also describe a preferred epoxy adhesion lift-off technique that is suitable for the fabrication of OPV devices.

### Materials and Methods for the Experimental Work

AgNWs were purchased from Seashell Technologies (San Diego, USA), which were supplied as a suspension (20.4 mg/mL) in isopropyl alcohol (IPA). An aliquot of the AgNW suspension was diluted to 0.1 mg/mL with IPA and stored until use. Carboxylate functionalized (P3 type) SWCNTs with purity of >90% were purchased from Carbon Solutions (California, USA). 50 mg of the carboxylate functionalized SWCNT were further purified by refluxing the SWCNTS in 3M HNO₃ for 12 hours and collecting via vacuum filtration (0.4 μm polycarbonate, Millipore). In this respect, mild acid treatment of SWCNTs improves aqueous dispersibility and performance of interwoven AgNW/SWCNT films.

A sample of the acid refluxed SWCNTs was suspended in water via probe sonication (Sonics Vibracell™) at 40% amplitude for 2 minutes before being diluted to a concentration of 0.25 mg/mL with deionized water. The lengths of the as-purchased AgNWs were shown to be in the order of 5 to 50 μm, with a diameter of approximately 100 to 200 nm. After the mild oxidation treatment, the SWCNTs were found to exist in bundles with a bundle diameter in the range of from 5 to 15 nm.

Sheet resistance measurements were performed using a four point probe (KeithLink® Technology Co., Ltd., New Taipei City, Taiwan). The values reported were an average of 10 measurements on two separate 64 mm² samples.

Transmission and reflectivity were measured on samples (25 mm²) using a Perkin-Elmer LAMBDA 950 UV/Vis/NIR Spectrophotometer with integrating sphere. The average transmission reported was for a wavelength range between 800-400 nm.

Scanning electron microscopy (SEM) images were acquired using a CamScan MX2500 (CamScan Optics, Cambridge, UK) working at an accelerating voltage of 10 kV and a distance of 10 mm.

Topographical atomic force microscopy (AFM) measurements were acquired using a Bruker Multimode AFM with Nanoscope V controller. NSC15 Mikromasch Silicon tapping mode probes with a nominal spring constant of 40 N/m, resonant frequency of 325 kHz and tip diameter equal to 20 nm were used. AFM images were acquired in tapping mode with all parameters including set-point, scan rate and feedback gains adjusted to optimize image quality and minimize imaging force.

Conductivity of the AgNW/SWCNT electrode eventually formed was mapped using peak force tunnelling AFM (PF-TUNA)²² on a Bruker Multimode AFM with Nanoscope V controller. The software used to acquire all AFM data was control software version 8.15.

The cantilevers used to obtain the PF-TUNA images were Bruker SCM-PIT conducting probes with a spring constant of 1-5 N/m. The entire cantilever and tip was coated with 20 nm of platinum and iridium resulting in a total tip diameter of approximately 40 nm. Root mean square roughness (Rᵣₘₛ) values were obtained from plane fitted image scans of 10 μm².

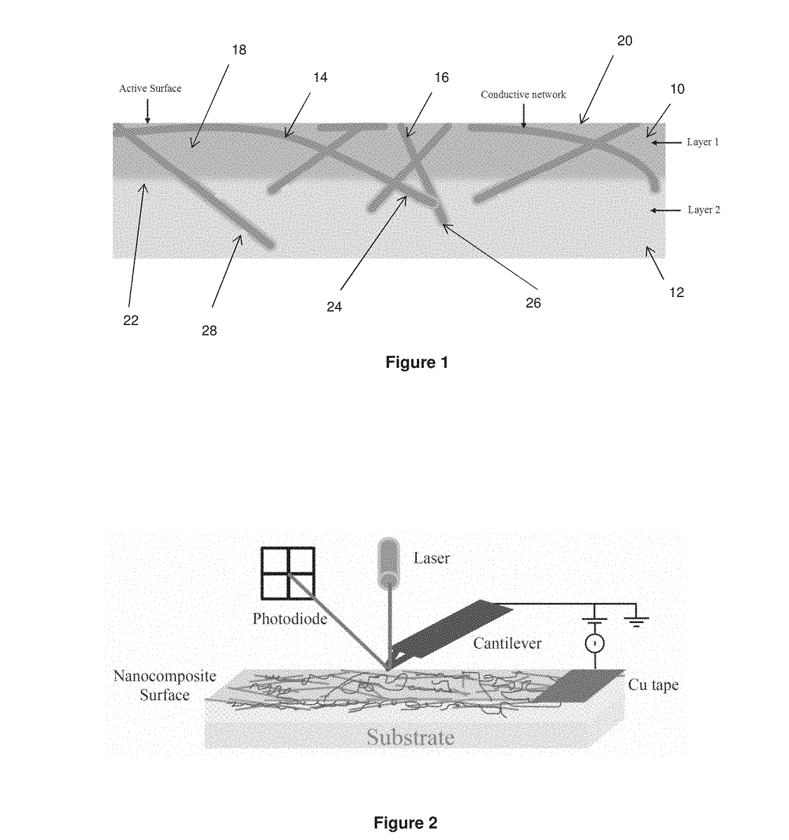

The samples surface was electrically connected via copper tape and the instrumental set up shown in FIG. 2.

PF-TUNA imaging parameters including set-point, scan rate, feedback gains, current sensitivity and applied bias were adjusted to optimize height and current image quality. The scanner was calibrated in x, y and z directions using silicon calibration grids (Bruker model numbers PG: 1 μm pitch, 110 nm depth and VGRP: 10 μm pitch, 180 nm depth).

For testing the AgNW/SWCNT based electrode materials of these embodiments in devices, two types of devices were fabricated using two different photoactive blends. The devices had the following structures (with schematic representations of these structures inset into FIG. 8) of substrate, conductive layer (including conductive network and conductive material), and base layer:
(1) Glass/AgNW/SWCNT/MoOx/poly(3-hexylthiophene-2,5-diyl) (P3HT):phenyl-C61-butyric acid methyl ester (PCBM)/Al
(2) Glass/AgNW/SWCNT/MoOx/poly[N-9″-heptadecanyl-2,7-carbazole-alt-5,5-(4′,7′-di-2-thienyl-2′,1′,3′-benzothiadiazole)](PCDTBT):[6,6]-phenyl C70-butyric acid methyl ester (PC70BM)/Al

Once the electrodes were fabricated, all steps of device fabrications and testing were carried out in an inert nitrogen environment (MBraun glove box, O2<0.1 ppm; H2O<0.1 ppm). A thin film of MoOx (Sigma Aldrich) was deposited as a buffer layer on the active surface of the electrodes using a thermal evaporator at a pressure ˜1×10-6 mbar. For devices with the P3HT:PCBM conductive layer (structure (1) above), a blend of P3HT:PCBM (1:1 w/w) was prepared by mixing equal amounts of individual solutions of P3HT (Merck) and PCBM (American Dye Source) in dichlorobenzene (DCB) (anhydrous grade). Both individual solutions had a concentration of 30 mg/mL.

The P3HT:PCBM blend was then filtered (0.22 μm PTFE filter, Membrane Solutions) and spin coated (500 rpm for 3 s, then 1400 rpm for 17 s) on top of the MoOx layer.

In a separate experiment for structure (2) above, a blend was prepared by mixing a 6 mg/mL solution of PCDTBT (SPJC, Canada) in DCB in a 24 mg/mL solution of PC70BM (Nano-C) in DCB. The PCDTBT:PC70BM (1:4 w/w) blend was then spin-coated (500 rpm for 3 s, then 800 rpm for 77 s) onto the MoOx layer. In this respect, a person skilled in the art will appreciate that a range of materials can be placed directly onto the conductive layer to alter the electronic properties of a device, such as work function, including, but not limited to, MoO, ZnO and PEDOT:PSS, to create an electrode with application dependent electronic properties while maintaining the conductive attributes of the conductive materials.

Both the structure (1) blend (P3HT:PCBM (1:1 w/w)) and the structure (2) blend (PCDTBT:PC70BM (1:4 w/w)) films were dried at 60° C. for 20 min on a hot plate. Finally, a thick layer of Al was deposited by thermal evaporation at a pressure of ˜1×10-6 mbar to complete the fabrication and form the opposite electrode for the device, in this configuration being the cathode. The final devices had an active area of 0.2 cm², which was defined using a shadow mask.

Finally, for testing device characteristics, an Abet Triple-A (Abet Technologies) solar simulator was used as the source. The solar mismatch of the Xenon lamp (550 W Oriel) spectrum was minimized using an AM1.5G filter. Light intensity at ˜100 mW/cm2 AM1.5G was calibrated by using a National Renewable Energy Laboratory (NREL) certified standard silicon photodiode (2 cm2), with a KG5 filter. A Keithley® 2400 source measurement unit was used for current density-voltage measurements.

### Preparation of Exemplary Planar AgNW/SWCNT Electrodes

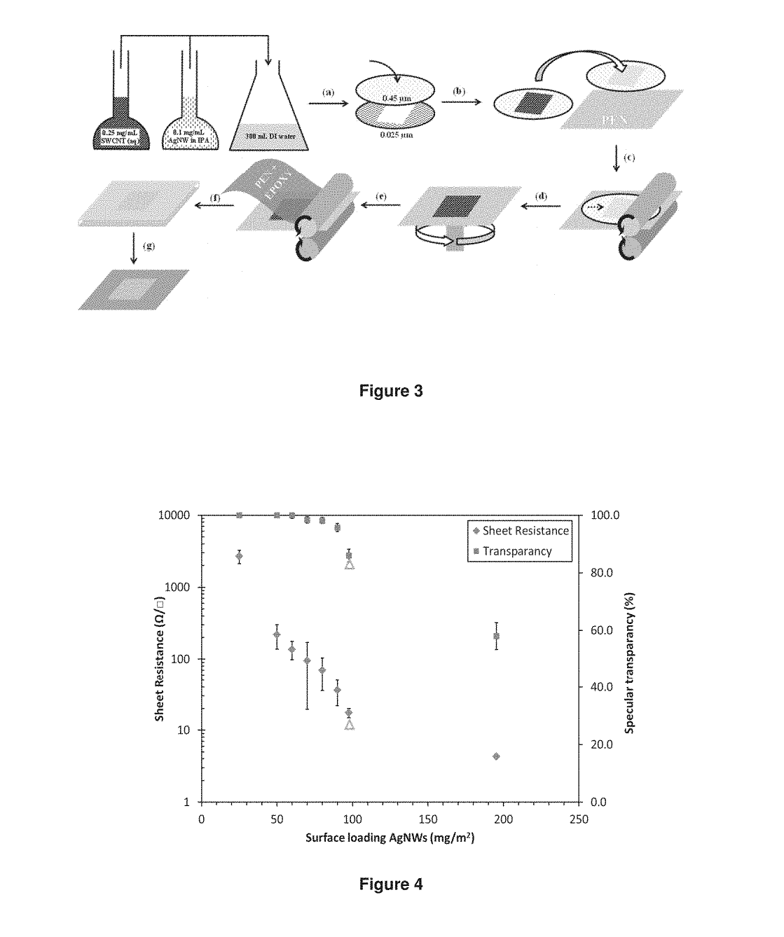

The raw base nanocomposite material for the conducting network (AgNW with 20 wt % SWCNT interwoven therewith) was prepared via vacuum filtration through mixed cellulose ester membranes (MF-Millipore Membrane, USA, mixed cellulose esters, hydrophilic, 0.4 μm, 47 mm). Reference here is made to the steps illustrated in the schematic of FIG. 3.

AgNW/SWCNT interwoven networks were prepared via vacuum filtration through mixed cellulose ester membranes (MF-Millipore Membrane, USA, mixed cellulose esters, hydrophilic, 0.4 μm, 47 mm). Various volumes of the prepared AgNW (0.1 mg/mL) and SWCNT (0.25 mg/mL) solutions were added to 300 mL of deionised water so that a AgNW are loading of 100 mg/m² was achieved in the final nanocomposite electrode.

In this respect, from the data shown in FIG. 4, it is apparent that in using the experimental method described above, there is a precipitous decrease in sheet resistance above a certain area loading of silver nanowires. It will be appreciated that as the size of the silver wires changes (length and width), and as the method of deposition changes (variations on the method described here being, such as, for example, spraying the solution), the preferred minimum area loading may vary. Similarly, as the density of the nanowires changes, the area loading also appears to change. The optimum area loading of silver nanowires is just above the point of the precipitous decrease in sheet resistance, as it will also typically correspond to the highest transmission for a conductive network

Returning to a discussion of the arrangement of FIG. 3, electrode patterning was achieved by placing a smaller pore size mixed cellulose ester template (MF-Millipore Membrane, mixed cellulose esters, hydrophilic, 0.025 μm, 47 mm) under the 0.4 μm membrane during filtration (FIG. 3(a)). After filtration, the patterned electrodes were then placed on untreated polyethylene naphthalate (PEN) (FIG. 3(b)). The PEN and patterned electrodes were then passed through a laminator at 130° C. (FIG. 3(c)). The mixed cellulose ester filter paper was subsequently removed with tweezers leaving behind the patterned AgNW/SWCNT nanocomposite on the surface of the PEN substrate.

Subsequently, 100 μL of 2:1 v/v PEDOT:PSS:IPA, was spin-cast on top of the AgNW/SWCNT nanocomposite at 500 rpm for 5 s then 3000 rpm for 30 s. The nanocomposite was then annealed at 140° C. for 10 min (FIG. 3(d)). 150 μL of Epotek 301 epoxy resin (T=99%) was then placed on top of the PEDOT:PSS coated AgNW/SWCNT electrode. A PEN sheet with surface treatment for adhesion was placed on top of the epoxy to create a PEN-AgNW/SWCNT-PEDOT:PSS-epoxy-PEN, stack (FIGS. 3(e and f)). The stack was heated at 65° C. for 1 h in an oven (Memmert, Germany) to cure the epoxy. The untreated PEN was peeled away to expose the smooth active surface of the electrode.

In order to achieve a suitable smooth active surface with good electron collection, a thin layer of solution processable conductive material is deposited which acts as both a charge distribution layer for free charges to migrate towards, and be collected by, the interwoven AgNW/SWCNT network, as well as a work function modification layer for subsequent layers in a device. This conductive layer also achieves “planarization” of the active surface, such that the active surface is smooth, assisting with the deposition of subsequent layers to create a required device.

In one embodiment, PEDOT:PSS was chosen as a conductive layer as it is a conducting polymer that also has the useful property that it can act as an electron blocking layer in OPV devices. This conductive material also encapsulates, and thus substantially coats, the conductive network which, without being bound by theory, is believed ensures that good electrical contact is maintained at the metal-metal interfaces as well as at the metal-nanotube interfaces.

In order to form the base layer, 150 μL of Epotek 301 epoxy resin (T=99%) was then placed on top of the PEDOT:PSS coated AgNW/SWCNT conductive layer. A glass substrate for transfer was placed on top of the epoxy to create a AgNW/SWCNT-PEDOT:PSS-epoxy-glass, or PEN, stack. The stack was heated at 65° C. for 1 h in an oven (Memmert, Germany) to cure the epoxy. In the case of Si, the stack was then put into liquid nitrogen in order to cleave the silicon-PEDOT:PSS interface, resulting in a smooth active surface attached to the glass substrate. In the case of a PEN planar template, the smooth active surface is exposed by peeling away the electrode from the planar template. The transmission of the resulting electrode was then measured using an integrating sphere and the results are shown in FIG. 4.

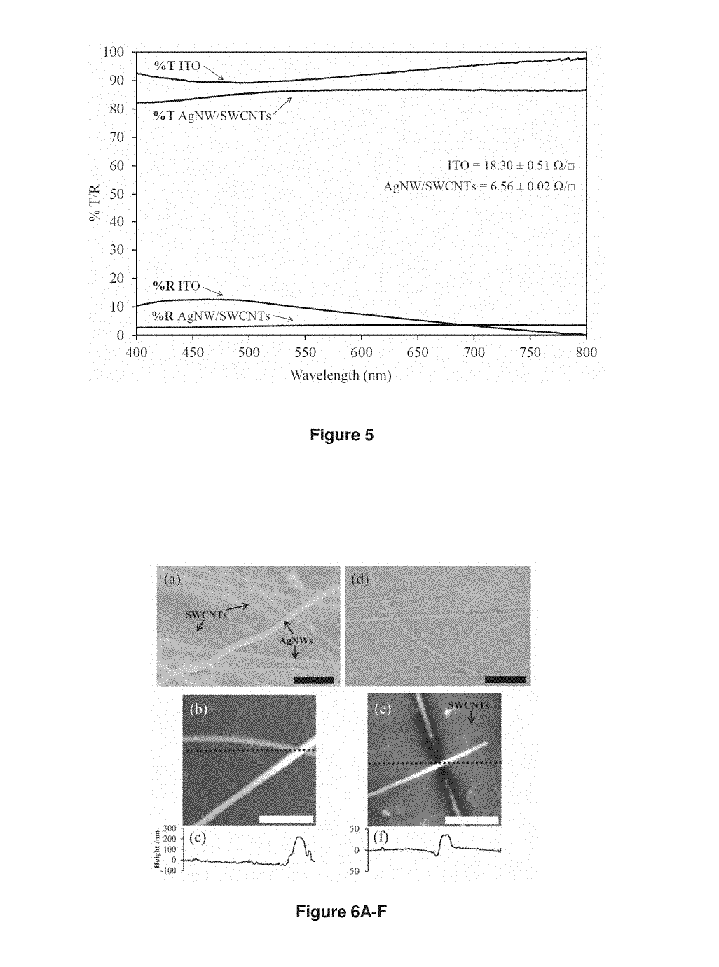

FIG. 5 (and Table 1, which will be described below) shows for the exemplary AgNW/SWCNT electrode over 800-400 nm that the average transmission was 86±1.4% and the average reflectivity was 3.4±0.3%. In contrast, for the prior art ITO electrode the average transmission was 93±6.5% and the average reflectivity was 7.2±4.3%.

The measured average sheet resistance of the exemplary AgNW/SWCNT electrode (6.56Ω/□) was almost half of that reported by prior art attempts at AgNW only electrodes (at 12Ω/□) and ITO electrodes (at 18.3Ω/□). Importantly, the exemplary AgNW/SWCNT electrode also has an average sheet resistance much lower than the prior art.

In order to quantify how well transparent electrodes formed using the materials of the present invention perform as conductors, a figure of merit value was calculated (see the results in Table 1 below). Such a figure of merit regularly used is the electrical to optical conductivity ratio (σ_DC/σ_OP) deduced from equations 1 and 2 below. A larger ratio indicates a better transparent conductor.

$$\begin{matrix}T = {( 1 + \frac{188.5}{{R}_{sh}} \cdot \frac{{σ}_{OP}}{{σ}_{DC}} )}^{- 2} \\ or & ( 1 ) \\ \frac{{σ}_{DC}}{{σ}_{OP}} = \frac{188.5}{{R}_{sh} \cdot ( {T}^{- 1 / 2} - 1 )} & ( 2 )\end{matrix}$$

where T=the average transmission at the wavelength of 500 nm

and Rₛₕ is the sheet resistance.

Typically, for planar electrodes with a polymer matrix, the σ_DC/σ_OP ratio lies between 186Ω-1 and 240Ω-1. The exemplary electrodes formed in these experiments have a σ_DC/σ_OP ratio of 367Ω-1, which are significantly improved over those of the Takada document mentioned above, as shown in Table 1.

The properties of an exemplary AgNW/SWCNT electrode and a prior art ITO electrode are summarised below in Table 1.

TABLE 1

| | Average | Average | Sheet | Figure of |
|---|---|---|---|---|
| | % T (800- | % R (800- | resistance | merit |
| | 400 nm) | 400 nm) | (Ω/□) | (σ_{DC}/σ_{OP}) |
| AgNW/SWCNT | 86 ± 1.4 | 3.4 ± 0.3 | 6.56 ± 0.02 | 367 |
| Large scale | 80-85 | — | 4-8 | 400-557 |
| 5 × 5 cm | | | | |
| AgNW/SWCNT | | | | |
| ITO | 93 ± 6.5 | 7.2 ± 4.3 | 18.30 ± 0.51 | 267 |
| Prior Art - | 84 | — | 10 | 207 |
| Takada | | | | |
| Document | | | | |

SEM (FIGS. 6(a) and 6(d)) and AFM (FIGS. 6(b) and 6(e)) images reveal that without the adoption of the structure of the conductive layer of the present invention, and thus without the smooth active surface of the present invention (FIG. 6(a)), the AgNW/SWCNT electrode has a complex active surface topography and exists as a simple interwoven network of AgNWs and SWCNTs with no binding matrix and a multitude of spaces and gaps therebetween. The reason for there being any type of association between the AgNWs and the SWCNTs, in these comparative examples, has been determined to be due to a solution phase interaction between the AgNWs and SWCNTs prior to deposition onto the cellulose ester membranes, which is different to a structure obtained by the sequential deposition of nanowires followed by nanotubes, which can have poorer performance.

With the adoption of the structure of the conductive layer of the present invention, the SEM reveals a significantly smoother active surface and substantially all of the AgNWs and SWCNTs are encapsulated in the PEDOT:PSS conductive material, with projecting (and encapsulated) AgNWs and SWCNTs embedded into the epoxy base layer (FIG. 6(d)), in the manner described more generally above.

The change in active surface morphology due to the encapsulation of the conductive network, and the active surface being smooth was also monitored via tapping mode AFM and the images are shown in FIG. 6(b) for a comparative (non-smooth) active surface and FIG. 6(e) for the smooth active surface. FIGS. 6(c) and 6(f) are the height profiles along the dotted lines in the AFM images of FIGS. 6(b) and 6(e). The height profile of a comparative AgNW/SWCNT active surface, not in accordance with the present invention, (FIG. 6(c)) shows that the surface topography of the comparative active surface exceeds a peak-to-trough height of 200 nm. This height profile is far above a preferred operational height for an efficient OPV device. In fact, all OPV devices fabricated from these comparative non-smooth active surfaces (those shown in FIGS. 6(a), 6(b) and 6(c)) displayed electrical characteristics of a short-circuited device.

On the other hand, FIG. 6(e) shows the surface morphology of an active surface of an exemplary AgNW/SWCNT electrode material, being in accordance with the present invention. It will be apparent that the height profile along the dotted line is significantly smoother than for the comparative active surface of FIG. 6(c), despite the fact that the height profile is positioned over the crossing point of two AgNWs. The roughness (Rq) of the exemplary active surface over a plane fitted image scan of 10 μm² was measured to be 3.5 nm. It should be noted that SWCNTs were still observed in the top right hand quadrant of FIG. 6(d) (see the arrow), indicating that the SWCNTs should participate in charge collection, passing collected charges to the more conductive AgNW network.

In this respect, PF-TUNA also provides evidence of the ability for SWCNTs to contribute to the charge collecting ability of the conductive network of an exemplary electrode as a secondary charge collecting network. The SWCNTs form part of the conductive network at the active surface of the electrode material of the present invention, being at least partly responsible for charge collection in OPV devices, and will presumably result in higher charge extraction efficiency and thus power conversion efficiency of an OPV device.

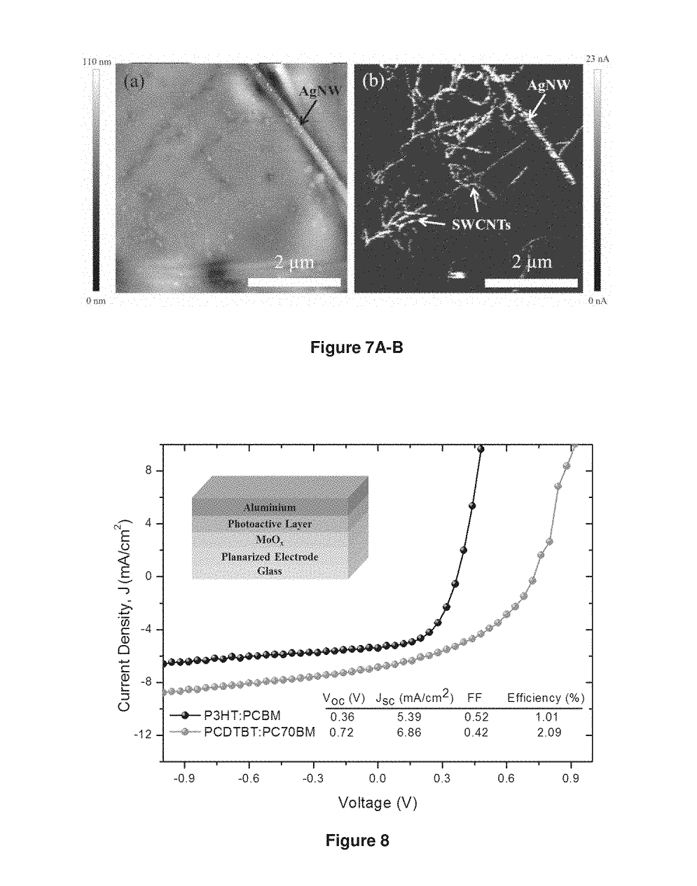

FIG. 7(a) shows the height image of the active surface of an exemplary electrode material where a silver nanowire is observed crossing the top right hand quadrant of the image. FIG. 7(b) shows the peak force current map of the active surface of an exemplary electrode material at a 2 V applied bias. It is apparent from FIG. 7(b) that the SWCNTs are electrically connected to the AgNW and are present in a significant density at the top surface (the active surface) of the electrode material, rendering the active surface electrically active. Importantly, at least some of the SWCNTs and the AgNWs remain electrically exposed at the active surface and are not completely covered by an epoxy, such as might be used as an adhesive layer in a traditional process of transferring a AgNW/SWCNT network to a glass substrate. If a non-conductive material, such as an epoxy, were to completely cover the SWCNTs and AgNWs, current would not be extractable from the active surface of the electrode and the sheet resistance would be in the mega-ohm range and completely unacceptable.

In one example of a device fabricated from the electrode material of the present invention, OPV devices were successfully fabricated on exemplary electrode materials using P3HT:PCBM and PCDTBT:PC71BM photoactive layers. Current density (J) and voltage (V) characteristics of the devices are shown in FIG. 8. P3HT:PCBM devices reached an efficiency of 1.01% while PCDTBT:PC70BM devices reached an efficiency of 2.09%. Device parameters including the open circuit voltage (VOC), short circuit current density (JSC), fill factor (FF) and efficiency are shown in FIG. 7.

In summary, it has been shown that electrodes based on interwoven AgNW and SWCNT's can be fabricated with a superior figure of merit—being a measure of the combination of transparency and conductivity—than prior art ITO electrodes on glass, and significantly better than prior art ITO electrodes on flexible substrates.

It has also been shown that the preferred SWCNTs are electrically connected to the preferred AgNWs, and are therefore expected to be able to act as extra charge collectors. The preferred method of fabrication is envisaged to be usable for a wide range of nanocomposite electrode compositions and potentially could be extended to use with other nanomaterials which have previously been overlooked due to surface topography. The preferred AgNW/SWCNT electrode materials of the present invention were used to fabricate efficient low temperature (annealing free) devices using two layer systems, demonstrating the potential of these electrodes to function with a range of semi-conducting polymer bulk heterojunctions.

It can be hypothesised that the inter-particle resistance, that is the resistance between the nanowires and between nanotubes and nanowires in an intimate mixture, will dominate the overall electrical conductivity. The relatively low viscosity of liquid polymer precursors, such as epoxy resins and the like, combined with the excellent surface wetting properties of these adhesive materials, can be expected to form an interfering layer between nanowires and nanotubes, thereby creating resistive elements in the non-conductive layer into which the nanowires penetrate. By encapsulating all of the nanowires and nanotubes with a conductive material, it is believed that the interparticle resistance can be reduced, and that the total current carrying capacity of the electrode increased, by effectively providing a thicker conductive element.

A person skilled in the art will understand that there may be variations and modifications other than those specifically described. It is to be understood that the invention includes all such variations and modifications. The invention also includes all steps, features, compositions and compounds referred to, or indicated in this specification, individually or collectively, and any and all combinations of any two or more of the steps or features

1. A transparent electrode material including a conductive layer having an active surface and a second surface, and an adjacent base layer, wherein:
the conductive layer includes a conductive network formed by metallic nanowires and carbon nanotubes encapsulated in a conductive material;
the second surface of the conductive layer has encapsulated nanowires and/or nanotubes projecting therefrom; and
the encapsulated nanowires and/or nanotubes projecting from the second surface of the conductive layer are embedded in the adjacent base layer;
whereby the active surface of the conductive layer is smooth and electrically active, and the transparent electrode material has a sheet resistance less than 50 Ω/sq and a transparency greater than 70%.

2. The transparent electrode material according to claim 1, wherein at least some of the metallic nanowires and carbon nanotubes of the conductive network are electrically exposed at the active surface.

3. The transparent electrode material according to claim 1, wherein the metallic nanowires are gold, silver or platinum nanowires, or a combination thereof.

4. The transparent electrode material according to claim 1, wherein the nanowires have a length in the range of 1 to 50 μm and a diameter in the range of 15 to 300 nm.

5. The transparent electrode material according to claim 1, wherein the carbon nanotubes are single-wall, double-wall or multi-wall carbon nanotubes, or a combination thereof.

6. The transparent electrode material according to claim 1, wherein the carbon nanotubes have a bundle diameter in the range of 5 to 150 nm, with individual nanotubes being in the range of 1 to 60 nm diameter.

7. The transparent electrode material according to claim 1, wherein the nanotube weight fraction in the conductive network is between 1 and 80 wt %.

8. The transparent electrode material according to claim 1, wherein the nanotube weight fraction in the conductive network is between 5 and 50 wt %, or between 15 and 30 wt %.

9. The transparent electrode material according to claim 1, wherein the area loading concentration (mg/m²) of nanowires in the conductive layer is between 10 and 250 mg/m².

10. The transparent electrode material according to claim 1, wherein the area loading concentration (mg/m²) of nanowires in the conductive layer is between 50 and 200 mg/m², or between 70 and 150 mg/m², or between 80 and 130 mg/m².

11. The transparent electrode material according to claim 1, wherein the conductive material is selected from a group of materials comprising semi-conducting polymers, metal oxides, and ultrathin metal films.

12. The transparent electrode material according to claim 1, wherein the conductive material is selected from a group of materials comprising poly(3,4-ethylenedioxythiophene):polystyrene sulfonate, poly(3-hexylthiophene-2,5-diyl), poly[(9,9-di-n-octylfluorenyl-2,7-diyl)-alt-(benzo[2,1,3]thiadiazol-4,8-diyl)], poly(9,9′-dioctyluorene-co-bis-N,N′-(4-butylphenyl)-bis-N,N′-phenyl-1,4-phenylenediamine), poly(9,9′-dioctyluorene-co-bis-N,N-(4-butylphenyl)-bis-N,N′-phenyl-1,4-phenylenediamine), ZnO, MoO, aluminium doped ZnO, Ni doped MoO, and ultrathin metal films of Au, Ag and Al.

13. The transparent electrode material according to claim 1, wherein the base layer is not a conductive material.

14. The transparent electrode material according to claim 1, wherein the base layer is selected from a group of materials comprising thermosetting materials, including epoxy resins and polyurethanes, and thermoplastic materials, including ethylene vinyl acetate (EVA).

15. The transparent electrode material according to claim 1, wherein the conductive layer has a thickness of between 5 nm and 300 nm.

16. The transparent electrode material according to claim 1, wherein the base layer has a thickness of between 1 micron and 1000 microns.

17. The transparent electrode material according to claim 1, wherein the active surface has a surface topography with a height profile having a peak-to-trough height of less than about 50 nm.

18. The transparent electrode material according to claim 1, wherein the active surface has a root mean square surface roughness of less than about 10 nm measured over a region of up to 10 micrometres.

19. A transparent electrode material including a first conductive layer having an active surface and a second surface, a second conductive layer having an active surface and a second surface, and a base layer between the first and second conductive layers, wherein:
the first and second conductive layers each include a conductive network formed by metallic nanowires and carbon nanotubes encapsulated in a conductive material;
the second surface of the first conductive layer and the second surface of the second conductive layer both have encapsulated nanowires and/or nanotubes projecting therefrom; and
the encapsulated nanowires and/or nanotubes projecting from the second surface of the first conductive layer and the second surface of the second conductive layer are embedded in the base layer;
whereby the active surface of the first conductive layer and the active surface of the second conductive layer are both smooth and electrically active, and the transparent electrode material has a sheet resistance less than 50 Ω/sq and a transparency greater than 70%.

20. The electrode formed from a transparent electrode material according to claim 1 or claim 19.

21. The optoelectronic device having an electrode in accordance with claim 20.

22. A method of forming a transparent electrode material, the method including:
forming a network of metallic nanowires and carbon nanotubes;
encapsulating the nanowire and nanotube network in a conductive material to form a conductive network in a conductive layer such that the conductive layer has a smooth active surface that is electrically active and a second surface, and such that the second surface has encapsulated nanowires and/or nanotubes projecting therefrom;
forming a base layer upon the second surface of the conductive layer to embed the projecting nanowires and nanotubes in the base layer;
whereby the transparent electrode material has a sheet resistance less than 50 Ω/sq and a transparency greater than 70%.

23. The method according to claim 22, wherein the method includes an acid reflux of the carbon nanotubes prior to forming the conductive network.

24. The method according to claim 22, wherein the forming of the network of metallic nanowires and carbon nanotubes includes co-depositing nanotubes with nanowires.

25. The method according to claim 22, wherein the forming of the network of metallic nanowires and carbon nanotubes is by way of a stamp transfer step.

26. A method of forming a transparent electrode material, the method including:
forming a first network of metallic nanowires and carbon nanotubes;
encapsulating the first nanowire and nanotube network in a conductive material to form a first conductive network in a conductive layer such that the first conductive layer has a smooth active surface that is electrically active and a second surface, and such that the second surface has encapsulated nanowires and/or nanotubes projecting therefrom;
forming a base layer upon the second surface of the first conductive layer such that the nanowires and nanotubes projecting from the second surface of the first conductive layer are embedded in the base layer;
forming a second network of metallic nanowires and carbon nanotubes;
encapsulating the second nanowire and nanotube network in a conductive material to form a second conductive network in a second conductive layer upon the base layer such that the second conductive layer has a smooth active surface that is electrically active and a second surface, and such that encapsulated nanowires and/or nanotubes project from the second surface of the second conductive layer to be embedded in the base layer;
whereby the transparent electrode material has a sheet resistance less than 50 Ω/sq and a transparency greater than 70%.
